(19) United States
(12) Patent Application Publication
(10) Pub. No.: US 2002/0139998 A1
(43) Pub. Date: Oct. 3, 2002

(54) Voltage offset diode

(75) Inventors: Philippe Dueme, Orsay (FR); Thierry Decaesteke, Montfort L'Amaury (FR)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THALES, PARIS (FR)

(21) Appl. No.: 10/001,978

(22) Filed: Dec. 5, 2001

(30) Foreign Application Priority Data
Dec. 22, 2000 (FR) 0016937

(51) Int. Cl. H01L 31/0336

(52) U.S. Cl. 257/200

(57) ABSTRACT

The interface device consists of a voltage offset diode (DD) constructed using monolithic microwave integrated technology, mounted between the output (S) of the upstream circuit (16) and the input of the downstream circuit (18). The characteristic of the offset diode (DD) is selected such that the bias voltage (VD) of the upstream circuit (16) is offset by an offset corresponding more or less to the disparity between the bias voltages (VD and VL) of the upstream (16) and downstream (8) circuits. The bias current of the downstream circuit is relatively high in comparison with the threshold current of the offset diode.

The present invention concerns a voltage offset diode constructed using microwave monolithic integrated technology. Said offset diode is intended to provide a voltage offset between two circuits where the downstream circuit consumes a relatively high bias current. For example, where the downstream circuit is a very broad band microwave electronic optic transmitter for producing an output ranging from a few Hz to several GHz, such as a laser diode.

It is used widely in the manufacture of Monolithic Microwave Integrated Circuits, or MMIC, and more particularly in electronic optics, for the transmission of microwave signals along optical fibres.

Electronic optic transmitters of the laser diode type for transmitting microwave signals on a very broad band are prior art.

For example, in patent FR 96 04 524, a distributed amplifier referred to as transimpedance acts as a low-impedance amplifier and adapter for a laser diode transmitting very broad band microwave signals.

In general, a distributed amplifier (simple or transimpedance) consists of a number of basic amplifier cells, mounted between an input line and an output line. Each basic amplifier cell consists of at least one field effect transistor, bipolar or similar. For example, in the case of field effect transistors mounted on a common feed, each transistor is linked to a common drain line (output line) by its drain as well as to a common gate line (input line) by its gate. Henceforth the description will be limited to field effect transistors, but a skilled person will know that he can easily transpose this invention to bipolar or similar transistors.

The correct operation of a field effect transistor requires the application of a direct bias voltage to its drain, and the application of a direct bias voltage to its gate.

In practice, bias filter circuits must allow direct bias voltages or currents through and isolate the microwave power. To this end (in particular in patent FR 96 04 524) the feed terminal which receives the bias voltage from the drains of the transistors is linked to a common drain line by means of a bias resistor and a bypass capacitor in parallel connected to ground. Further a coupling capacitor is provided between the common drain line, which forms the output of the distributed amplifier, and the anode of the laser diode.

Such a coupling capacitor isolates the microwave power from the direct bias. However, it also prevents the passage of the low frequencies, for example those under 500 MHz, which are demanded by certain applications for transmission of microwave signals.

One solution to this problem, involves supplementing the coupling capacitor by a high value capacitor mounted on the outside of the circuit to increase the impedance of the coupling capacitor. However this cannot be considered here. In fact, unlike a bypass capacitor, one of the armatures of which is connected to ground, a coupling capacitor is placed between two non-zero voltage points, which prevents the fitting of a capacitor external to the integrated circuit (MMIC chip).

It is an object of the present invention to overcome, or at least mitigate, the above problem.

The present invention concerns an interface device between two circuits, whereby the upstream circuit comprises of an output and means of direct voltage bias, and whereby the downstream circuit consists of an input, uses a direct bias voltage with a higher value than that of the downstream circuit and consumes a relatively high bias current which is a function of the power delivered by the downstream circuit.

According to a general definition of the present invention, the interface device consists of a voltage offset diode mounted between the output of the upstream circuit and the input of the downstream circuit, the characteristic of the offset diode being selected such that the bias voltage of the upstream circuit is offset by an offset corresponding more or less to the disparity between the bias voltages of the upstream and downstream circuits and the value of which corresponds more or less to the threshold voltage of the offset diode, and the bias current of the upstream voltage being relatively large in relation to the threshold current of the offset diode.

Such an offset diode makes it possible to cut out the coupling capacitor between the upstream and downstream circuits, which renders said upstream circuit suitable for functioning in a very broad frequency band, ranging from a few Hz to several GHz.

Even though diodes constructed in microwave monolithic integrated technology are prior art (patent application FR-A-2661790), the skilled person is not in any way prompted to use them in order to cut out a coupling capacitor while at the same time allowing through a relatively high bias current, which is a function of the power delivered by the downstream circuit. It should be noted that in patent application FR-A-2661790, a diode bridge is used in a negative feedback loop into which a relatively weak current is passed which is more or less equal to the threshold current of the elementary diodes of the diode bridge.

The offset diode may comprise a number of transistors constructed in microwave monolithic integrated technology mounted in parallel between the output of the upstream circuit and the input of the downstream circuit.

In a preferred embodiment of the invention, each transistor of the offset diode includes a drain and a source linked to each other, each finger of the gate forming a diode effect contact.

The downstream circuit may includes a laser diode capable of transmitting very broad band microwave signals.

The upstream circuit may include a control circuit for the laser diode of 50 ohms impedance and a distributed power amplifier acting as a low impedance adapter.

In order that the invention may be more clearly understood embodiments thereof will now be described by way of example with reference to the accompanying drawings in which:

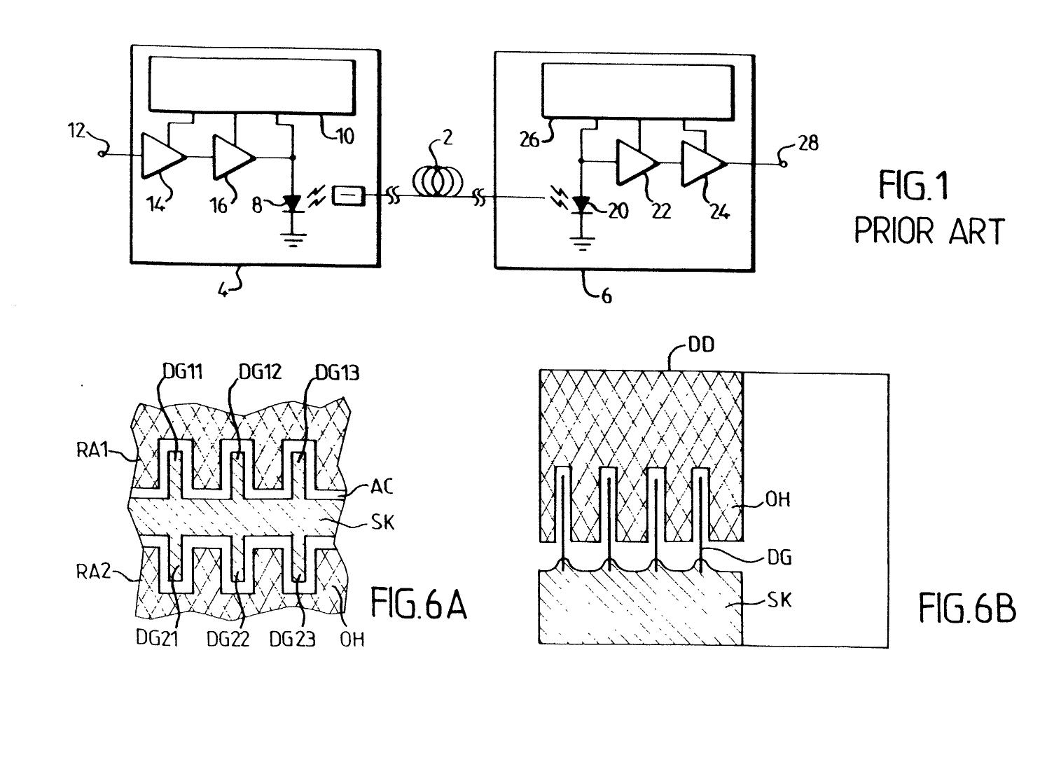

FIG. 1 is a diagram of a microwave telecommunications link on optical fibre between a laser diode and a photodiode, according to prior art;

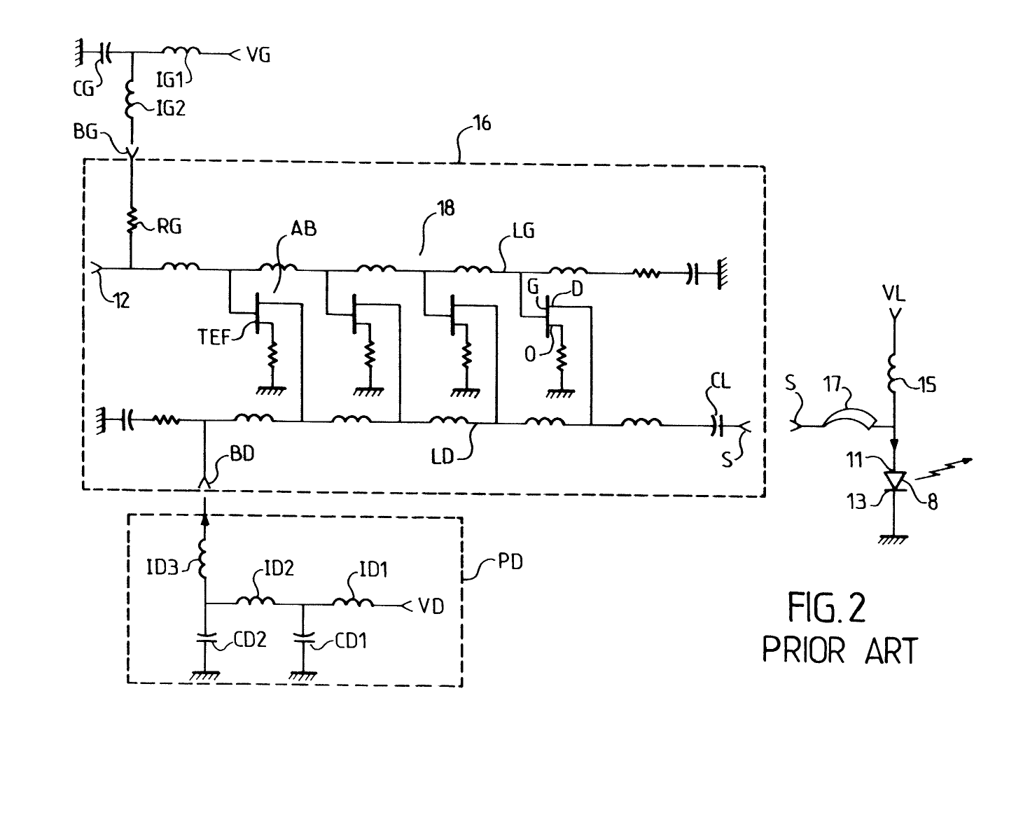

FIG. 2 is a diagram of a distributed amplifier of prior art connected to the input of the laser diode described in reference to FIG. 1;

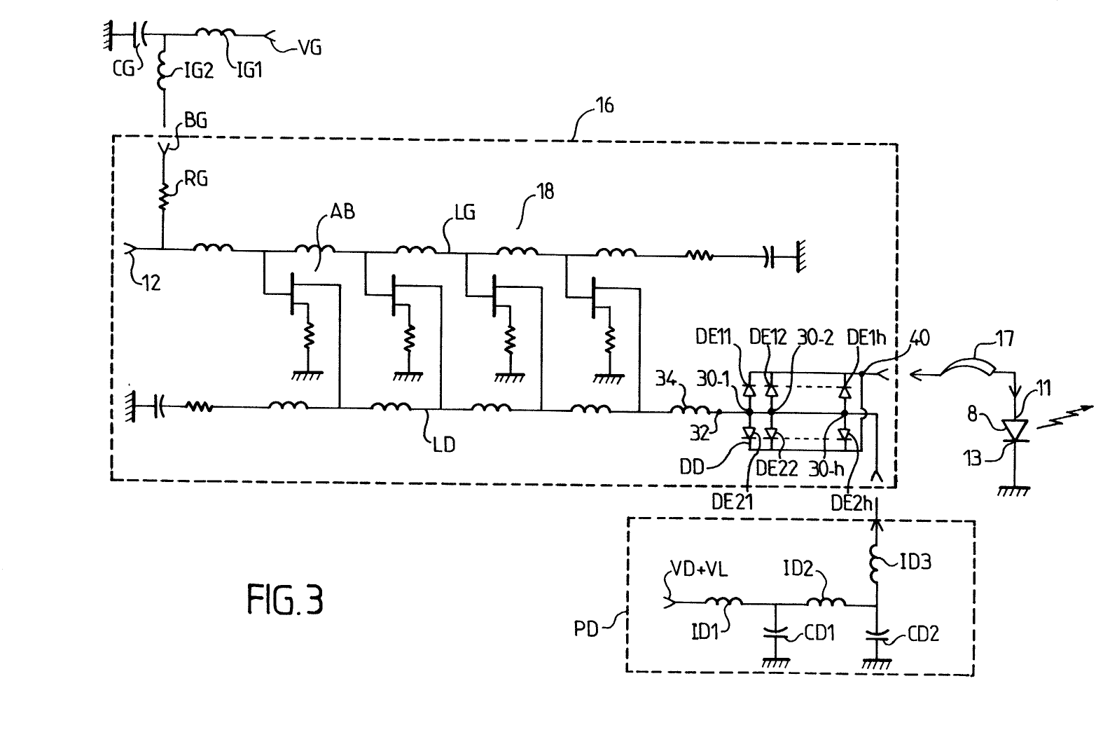

FIG. 3 is a schematic representation of the distributed amplifier in FIG. 2, connected to the input of the laser diode by means of a voltage offset diode according to invention;

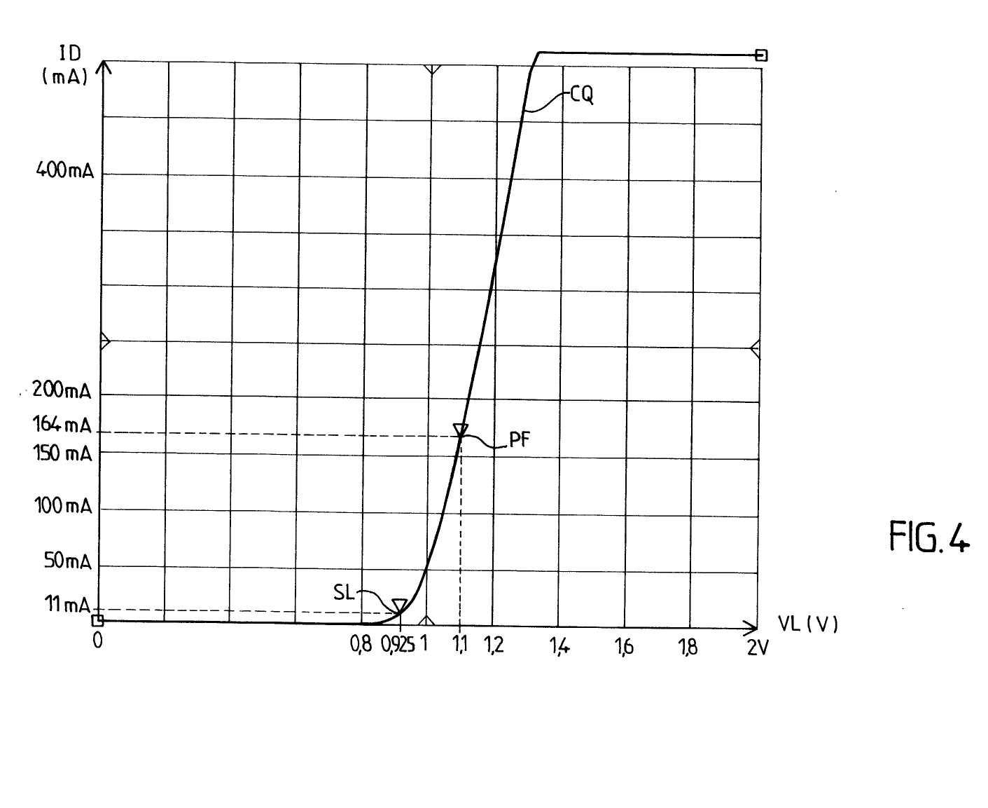

FIG. 4 is a drawing showing the characteristic of the voltage offset diode according to invention;

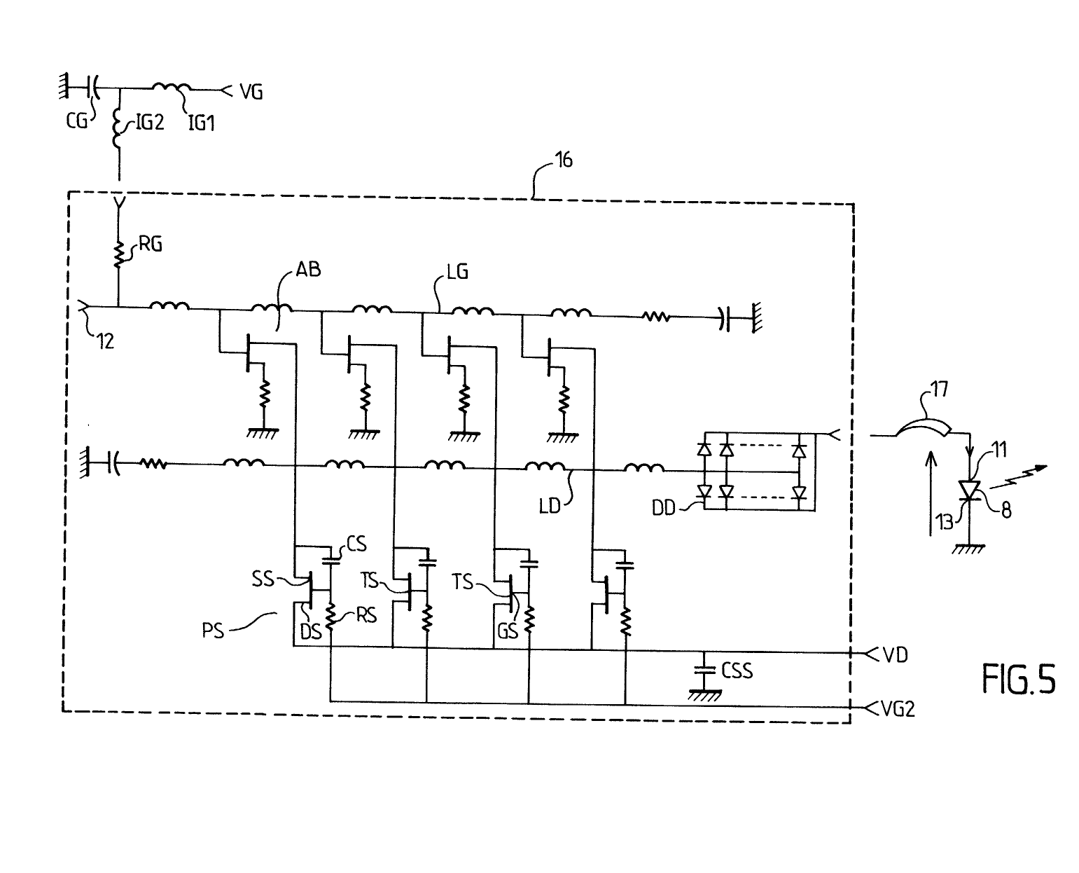

FIG. 5 is a variant of realisation according to invention of the distributed amplifier from FIG. 3, in which the bias circuit of the common drain line uses additional transistors operating as saturable load;

FIGS. 6A and 6B schematically represent the modes of realisation of the gate fingers of the transistors of the offset diode according to invention; and

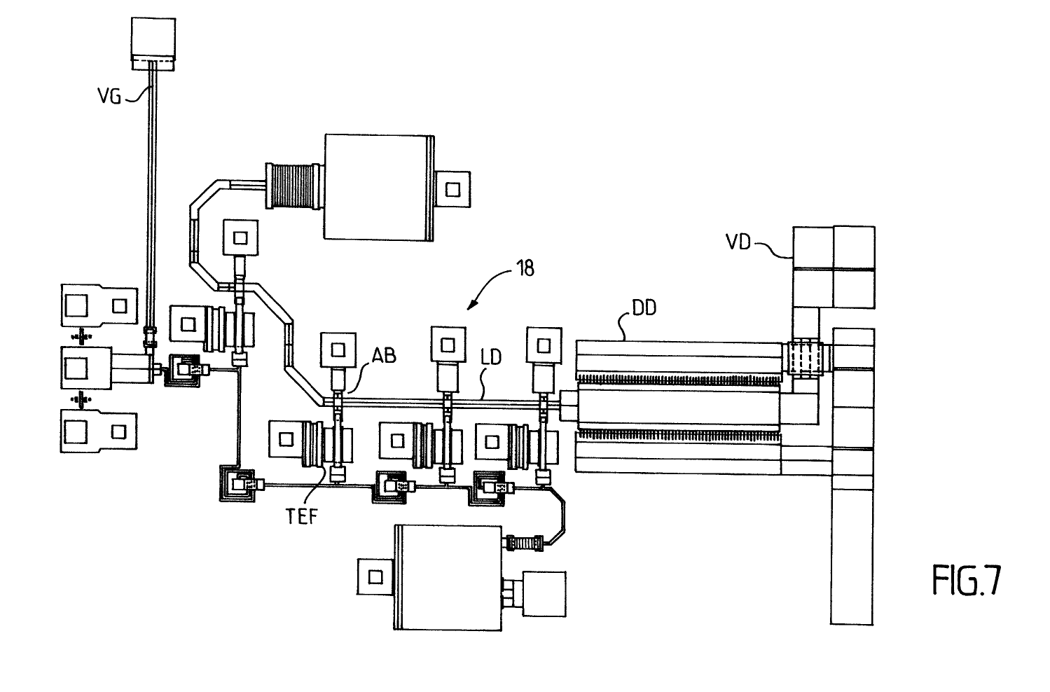

FIG. 7 schematically represents a mask of a circuit realised in MMIC technology containing the distributed amplifier and the offset diode according to invention.

The drawings comprise some elements of a particular nature. For this reason, they may serve, not only to make the invention better understood, but also to contribute to its definition, if necessary.

Referring to FIG. 1, this shows a very high speed microwave telecommunication fibre optic link 2 between a transmission tip 4 and a receiving tip 6. The link uses direct amplitude modulation. The transmission tip 4 comprises a laser diode 8, the current of which is modulated by the incident radio frequency and microwave signal 12. The transmission tip 4 consists of a bias device 10, if necessary a pre-amplification stage 14, and an amplification and impedance adaptation stage 16.

Stage 16 performs an adaptation between the low impedance of the laser diode (in the order of 10 ohms) and the ordinary impedance (50 ohms) of the input device (controller) of the laser diode.

On the receiver tip side 6, a photodiode 20 captures the signals transmitted by the optical fibre 2. The receiver tip 6 also includes an impedance adaptation stage 22, if necessary a pre-amplification stage 24, and a bias device for the photodiode 26. The output 28 of the receiver tip can issue a very broad band microwave signal ranging from a few Hz to several GHz.

In reference to FIG. 2, the stage 16 consists of a distributed amplifier 18 referred to as a transimpedance which acts as the low impedance amplifier and adapter for the laser diode 8.

The prior art distributed amplifier 18 consists of a number of base amplifier cells AB, mounted between an input line (common drain line LD in the case of field effect transistors mounted as common feed) and an output line (common gate line LG). Each base amplifier cell AB consists of at least one field effect transistor mounted as common feed 0 and linked to the common drain line LD by its drain D as well as to the common gate line LG by its gate G.

The correct operation of a field effect transistor requires the application of a direct bias voltage VD on its drain D, and the application of a direct bias voltage VG on its gate G.

The feed terminal BG which receives the bias voltage VG from the gates of the transistors is linked to the common gate line LG via a resistor RG (in the order of 1 kilo ohm, for example) and a bypass capacitor CG in parallel connected to ground. The leading wires IG1 and IG2 connect the power supply delivering the voltage VG to the terminal BG.

The common drain line LD has a biased voltage VD via a power filter circuit PD linked to the power supply terminal BD via inductive resistors ID1, ID2 and ID3 and the bypass capacitors CD1 and CD2 in parallel and connected to ground.

The output S of the distributed amplifier 18 is linked to the anode 11 of the laser diode 8 by means of a ribbon or wire 17. The cathode 13 of the laser diode 8 is connected to ground. The laser diode 8 is biased according to a continuous bias voltage VL by means of an inductance 15, for example in the order of 13 mH.

For example, the current of the laser diode 8 is in the order of 150 mA and the voltage of the laser diode 8 is in the order of 1.4 V.

A coupling capacitor CL is provided in accordance with prior art between the end of the common drain line LD which forms the output S of the distributed amplifier and the anode 11 of the laser diode 8 (via the ribbon 17).

As seen above, such a coupling capacitor CL isolates the microwave power from the continuous bias. But such a coupling capacitor CL also prevents low frequencies from passing.

With reference to FIG. 3, this shows the distributed amplifier 18 described in reference to FIG. 2 in which in particular the coupling capacitor 18 has been replaced by an offset diode DD according to invention.

The voltage offset diode DD is mounted between the end 32 of an inductor 34 forming the output S of the distributed amplifier 18 and the anode 11 of the laser diode 8 by means of the wire or ribbon 17.

In practice, the offset diode consists of a number of transistors manufactured in broadband monolithic microwave technology and mounted in parallel between the output of the upstream circuit and the input of the downstream circuit.

Preferably, each transistor of the offset diode includes a drain and a source linked together, which forms an elementary diode DE.

With reference to FIG. 3, the offset diode DD consists, for example, of two arrays RA1 and RA2 of elementary diodes DE mounted in parallel between the output of the distributed amplifier and the laser diode.

The first array RA1 of elementary diodes DE comprises n diodes numbered in series from DE11 to DE1n, with for example n equal to 74 and the second array R2 of elementary diodes comprises n diodes numbered in series from DE21 to DE2n, with for example n equal to 74.

The elementary diodes DE are placed in an arrangement in which the node 30-1 is connected in series to the output (in this case, the end of the inductor 34) of the distributed amplifier and in parallel to the anode of diode DE 11 and to the anode of diode DE21. In turn, node 30-2 is connected in series to node 30-1, and in parallel to the anode of diode DE12 and to the anode of diode DE22. In the same way, node 30-n is connected in series to node 30-n-1, and in parallel to the anode of diode DE1n and to the anode of diode DE2n.

The cathodes of the elementary diodes DE are connected to node 40 which is intended to be connected to the anode of the laser diode 8, via the ribbon 17 (as necessary).

Node 30-n can advantageously act as the supply terminal which receives the bias voltage from the common drain line LD by means of the filter circuit PD described in reference to FIG. 2.

According to invention, the filter circuit PD can also act as the filter for the bias voltage VL from the laser diode 8, which makes it possible to cut out the inductor 15 described in reference to FIG. 2.

In reference to FIG. 4, this shows the characteristic CQ of the offset diode DD which supplies the direct voltage VL (in volts) to the terminals of the offset diode DD as a function of the field strength ID (in amperes) across it.

The offset diode DD is selected such that the bias voltage VD of the common drain line LD is offset by an offset corresponding more or less to the disparity between the bias voltage VD of the common drain line LD and the bias voltage VL of the laser diode.

In practice, the operating point PF of the offset diode is selected as equal to 1.1 V with a maximum strength of utilisation of 164 mA and the threshold SL of the offset diode is selected as equal to 0.925 V with a minimum strength of 11 mA. The threshold current (here, 11 mA) of the offset diode is thus relatively low in relation to the current consumed by the downstream circuit (here, 164 mA).

With a bias voltage of the laser diode VL in the order of 1.4 V and a bias voltage of the common drain line VD in the order of 2.5 V, the voltage offset is thus in the order of 1.1 V, which corresponds more or less to the value of the operating point PF of the offset diode DD.

By cutting out the coupling capacitor CL between the upstream circuit 16 and the downstream circuit 8 and replacing it by the offset diode DD, the laser diode 8 can operate in a very broad band of frequency, ranging for example from a few Hz to several GHz.

In reference to FIG. 5, the supply filter circuit PD of the voltage VD of the common drain line described in reference to FIGS. 2 and 3 has been replaced by a bias filter circuit PS using supplementary transistors TS operating as saturable load.

In practice, the circuit PS consists of a number of supplementary transistors TS operating as saturable load. The sources SS of the supplementary transistors TS are distributively connected to the common drain line LD.

The drains DS of the supplementary transistors TS receive the bias voltage VD in series.

The gates GS of the supplementary transistors receive a second gate bias voltage VG2 in series, as appropriate, via a supplementary resistor RS respectively. In practice, the voltage VG2 is connected to ground in parallel via a bypass capacitor CSS.

Furthermore, each supplementary gate is connected to its respective source by means of a supplementary capacitor CS.

The circuit PS remedies the problems (loss of energy, bulkiness) resulting from the filtration of the bias circuits by means of the terminal resistors RG, such as that described in reference to FIG. 2.

In the same way, the circuit PS remedies the problems (degradation of performances, impedance mismatch, resonance, bulkiness, solder joints) resulting from the filtration of the bias circuits by means of the inductive elements 15, ID1, ID2 and ID3 like those described in reference to FIGS. 2 and/or 3.

In reference to FIG. 6A, this shows one mode of realisation of the offset diode which consists of a number of field effect transistors produced using microwave monolithic integrated technology.

The offset diode DD for example consists of two arrays RA1 and RA2 of n transistors. Each transistor forms an elementary diode DE by connecting its drain to its source.

Each transistor includes a gate finger DG, numbered in series from DG11 to DG1n for the first array RA1 and from DG21 to DG2n for the second array RA2.

For example, the current of each gate finger DG is less than 1 microamp (for n=148) and the bias current VD of the drain line LD is in the order of 150 to 300 microamps.

Each gate finger DG of the diode DD is realised in accordance with a contact referred to as a “Schottky” SK, similar to the gates of the field effect transistors. In practice, a “Schottky” contact SK is a metal/semi-conductor contact which results in an emission potential AC. Such a “Schottky” contact presents a diode effect.

Alternatively, the drains and sources of the transistors of the offset diode may be realised according to a contact known as “ohmic” OH which is a metal/semi-conductor contact requiring more complex metallurgy than that of the Schottky contact SK. Such an ohmic contact usually involves materials such as germanium, gold, or gallium arsenide, and results in the absence of an emission potential. So this is a contact without a diode effect, with a low resistance.

The intermediate area AC between the ohmic contact and the Schottky contact is an active area.

Each gate finger has an individual development in the order of 5 micrometers. So the offset diode has a total gate development in the order of 148×5 micrometers, thus in the order of 740 micrometers.

Referring to FIG. 7, this shows a mask which illustrates the realisation of the circuit 16 described in reference to FIG. 3 and which consists of a distributed amplifier 18 according to invention and an offset diode DD.

Referring to FIG. 6B, this shows an enlarged portion of the mask of the offset diode in which the gate fingers DG can be clearly seen.

The above embodiments are described by way of example only. Many variations are possible without departing from the invention as defined by the following claims.

1. Device for use as an interface between an upstream circuit and a downstream circuit in which the upstream circuit comprises an output and means for applying a direct bias voltage to the output and the downstream circuit comprises an input requiring a direct bias voltage greater than that applied to the output of the upstream circuit, the downstream circuit consuming a relatively large bias current which is a function of power delivered by the downstream circuit, the device comprising a voltage-offset diode realised in microwave monolithic integrated technology for mounting between the output of the upstream circuit and the input of the downstream circuit, the characteristic of the voltage-offset diode being selected such that the bias voltage of the output of the upstream circuit is offset by an offset corresponding more or less to the difference between the bias voltages of the output of the upstream circuit and the input of the downstream circuit, and the bias current of the downstream circuit is relatively high in relation to the threshold current of the offset diode.

2. Device according to claim 1, characterised in that the offset diode comprises a number of transistors mounted in parallel between the output of the upstream circuit and the input of the downstream circuit.

3. Device according to claim 2, characterised in that each transistor of the offset diode comprises a drain and a source connected to each other, the gate finger of each transistor forming a contact with diode effect.

4. Device according to one of claims 1 to 3, characterised in that the downstream circuit comprises a laser diode capable of emitting very broad band microwave signals.

5. Device according to claim 4, characterised in that the upstream circuit consists of a control circuit for the laser diode, the impedance of which is 50 ohms.

6. Device according to claim 4, characterised in that the downstream circuit has a low impedance, in the order of a few ohms.

7. Device according to claim 4, characterised in that the downstream circuit further includes a distributed amplifier as low-impedance adapter.

8. Device according to claim 7, characterised in that the distributed amplifier consists of a number of amplifier cells mounted between an input line and an output line, one of the ends of the input line forming the input of the distributed amplifier and being connected to the control circuit of the laser diode, one of the ends of the output line forming the output of the distributed amplifier, and the means of bias of the upstream circuit applying a bias voltage to the output line.

9. Device according to claim 1, characterised in that the bias current of the downstream circuit is in the order of a few dozen mA.

10. Device according to claim 3 or claim 9, characterised in that the individual development of each gate finger is in the order of a few micrometers and in that the total development of the offset diode is in the order of a few dozen micrometers.

11. Device according to one of the preceding claims, characterised in that it also includes a bias filter circuit of the output line, comprising a device with transistors acting as saturable load.

12. Electric apparatus comprising an upstream circuit having an output and means for applying a direct bias voltage to the output, a downstream circuit having an input and means for applying a direct bias voltage to the input, the direct biasing voltage applied to the input of the downstream circuit being greater than that applied to the output of the upstream circuit, and a device as claimed in claim 1 mounted between the output of the upstream circuit and the input of the downstream circuit.
